(19) United States
(12) Patent Application Publication
(10) Pub. No.: US 2006/0040481 A1
(43) Pub. Date: Feb. 23, 2006

(54) Methods and structures for preventing gate salicidation and for forming source and drain salicidation and for forming semiconductor device

(76) Inventors: Bor-Wen Chan, Hsin-Chu (TW); Yu-Shen Lai, Hsinchu City (TW)

Correspondence Address: DUANE MORRIS LLP;IP DEPARTMENT (TSMC), 30 SOUTH 17TH STREET, PHILADELPHIA, PA, 19103-4196, US

(21) Appl. No.: 10/919,571

(22) Filed: Aug. 17, 2004

(51) Int. Cl. H01L 21/3205

(52) U.S. Cl. 438/585

(57) ABSTRACT

Methods and structures for preventing salicidation are disclosed. A substrate has an gate electrode on it. Spacers are on sidewalls of the gate electrode, exposing a top portion of the gate electrode. A dielectric layer is formed above the spacers, covering the exposed top portion of the gate electrode. Methods and structures for forming source and drain salicidation are disclosed. They further salicidize source and drain regions which are adjacent to the spacers without forming salicidation on the gate electrode while salicidizing the source and drain regions. Methods and structures for forming gate electrode salicidation are also disclosed. They further form another dielectric layer covering the salicidized source and drain regions. A portion of the dielectric layer is removed so as to expose a top surface of the gate electrode. The gate electrode is then salicidized.

### FIELD OF THE INVENTION

The present invention relates to the fabrication of integrated circuit devices on semiconductor substrates and, more particularly relates to structures and methods for preventing the formation of silicide on the poly gate, structures and methods for forming source and drain salicidation and structures and method for forming semiconductor devices.

### BACKGROUND OF THE INVENTION

The Complementary Metal Oxide Semiconductor (CMOS) technology has been recognized as the leading technology for use in digital electronics in general and for use in many computer products in particular. The miniaturization of CMOS technology according to a scaling rule is used in a semiconductor device to achieve large-scale integration and high-speed operation. In CMOS devices, the miniaturization leads to a decrease in the threshold voltage due to shortening of the channel. By the decrease of the threshold voltage, the MOS devices can achieve high speed performances.

Usually, gate electrodes of the MOS devices are composed of polysilicon. With semiconductor properties, polysilicon is a widely used material during manufacturing. A number of processes are performed during semiconductor manufacturing. They include thin film deposition, ion implantation, etch and photolithography. Due to ion implantation which is near to the polysilicon gate electrode and doped thin film deposition, the polysilicon gate electrode is subject to the diffusion of ions in or out of the polysilicon gate electrode. The diffusion affects the dopant concentration of the polysilicon gate electrode. In addition, during operation of the polysilicon gate electrode, a depletion region occurs in the polysilicon gate electrode because of applying a voltage thereon. The combination of the ion diffusion and the effect of depletion raises the equivalent oxide thickness (Tox) of the gate dielectric layer. Due to the enhancing of the Tox, the threshold voltage of the MOS devices rises. This phenomenon lowers the operational speed of the MOS devices. Accordingly, a method of forming a metal gate electrode is proposed to resolve the issue because the metal gate electrode prevents ion diffusion and avoids the depletion effect.

The method of forming the metal gate electrode substantially completely transforms a polysilicon gate electrode into a metal gate electrode. The transformation of the gate electrode may be applied to a gate electrode which has thickness grater than the depth of source and drain regions in order to form shallow junctions at the source and drain regions. Accordingly, a traditional method that forms salicidized gate electrode, source and drain regions cannot be applied due to the concern that it either fails to completely transform the polysilicon gate electrode into the metal gate electrode or forms the deep junctions at the source and drain regions. The salicidaiton of the gate electrode, and the source and drain regions should be separated.

FIGS. 1A and 1B are schematic cross sectional progression steps of a prior method for forming a metal gate electrode.

FIG. 1A shows a substrate 100 having a polysilicon gate electrode 120 thereon. Liner layers 105 are formed on the sidewalls of the polysilicon gate electrode 120 and on the substrate 100. Spacers 110 are formed on the liner layers 105. A mask layer 130 is formed on the polysilicon gate electrode 120. The liner layers 105 are vulnerable to an etch-back process for forming the spacers 110. As a result, divots 145 are formed on the liner layers 105, exposing portions of the sidewalls of the polysilicon gate electrode 120.

Referring to FIG. 1B, salicidized source and drain regions 160 are formed in the substrate 100. Due to the exposed sidewalls 140, the metal layer (not shown) used for salicidation contacts the polysilicon gate electrode 120. During the salicidation of the source and drain regions 160, the metallic atoms penetrate into polysilicon gate electrode 120 and salicidation also occurs at the exposed sidewalls 140. Accordingly, the salicidation of the source and drain regions 160 forms the salicidized gate electrode 150 at the top of the gate electrode 120. The metallic atoms penetrate into polysilicon gate electrode 120. Due to the formation of the salicidized gate electrode 150, contamination issues may be confronted in the subsequent processes.

U.S. Pat. No. 4,912,061 (Nasr) entitled: “Method of forming a salicided self-aligned metal oxide semiconductor device using a disposable silicon nitride spacer”—shows double spacers (oxide and nitride)on the sidewalls of a gate. The method is related to a SALICIDED complementary metal oxide semiconductor utilizing very thin oxide spacers and a disposable nitride layer.

U.S. Pat. No. 5,663,586 (Lin) shows an FET device with double spacers. This patent is related to an improved FET device in which the hot carrier immunity and current driving capability are improved, and the subthreshold leakage current is minimized.

U.S. Pat. No. 5,208,472 (Su) entitled: “Double spacer salicide MOS device and method”—shows multilayer dielectrics used at the edge of the gate electrode. The gate electrode, the source and the drain have metal silicide regions.

U.S. Pat. No. 5,923,986 (Shen) has an object to provide a method for fabricating a wide top spacer for a salicide process that reduces the salicide bridging and shorting.

None of these patents mention forming a structure to prevent gate electrode salicidation.

### SUMMARY OF THE INVENTION

An exemplary method for preventing salicidation is disclosed. The method first provides a substrate having a gate electrode thereon. Spacers are on sidewalls of the gate electrode, exposing a top portion of the gate electrode. The method then forms a dielectric layer above the spacers, covering the exposed top portion of the gate electrode.

An exemplary method for preventing salicidation is disclosed. The method first provides a substrate having a gate electrode thereon. Liner layers are on the substrate and sidewalls of the gate electrode, exposing a top portion of the gate electrode. Spacers are on the liner layers. A dielectric layer is then formed, covering the exposed top portion of the gate electrode.

An exemplary method of salicidizing source and drain regions is disclosed. The method comprises first providing a substrate having a gate electrode thereon. Spacers are on sidewalls of the gate electrode, exposing a top portion of the gate electrode. The method then forms a dielectric layer above the spacers, covering the exposed top portion of the gate electrode. The method then salicidizes source and drain regions which are adjacent to the spacers without forming salicidation on the gate electrode while salicidizing the source and drain regions.

An exemplary method of salicidizing a gate electrode is disclosed. The method comprises first providing a substrate having a gate electrode thereon. Spacers are on sidewalls of the gate electrode, exposing a top portion of the gate electrode. The method then forms a first dielectric layer above the spacers, covering the exposed top portion of the gate electrode. The method then salicidizes source and drain regions which are adjacent to the spacers without forming salicidation on the gate electrode during salicidizing the source and drain regions. A second dielectric layer is formed, covering the salicidized source and drain regions. A portion of the first dielectric layer is removed so as to expose a top surface of the gate electrode. The gate electrode is salicidized.

An exemplary structure for preventing salicidation is disclosed. The structure comprises: a substrate, a gate electrode, spacers and a dielectric layer. The gate electrode is on the substrate. The mask layer is on the gate electrode. The spacers are no sidewalls of the gate electrode, exposing a top portion of the gate electrode. The dielectric layer is above the spacers, covering the exposed top portion of the gate electrode.

An exemplary structure for preventing salicidation is disclosed. The structure comprises: a substrate, a gate electrode, spacers and a dielectric layer. The gate electrode is on the substrate. The mask layer is on the gate electrode. The spacers are on sidewalls of the gate electrode, exposing a top portion of the gate electrode. The dielectric layer is above the spacers, covering the exposed top portion of the gate electrode.

An exemplary structure for preventing salicidation is also disclosed. The structure comprises a substrate having a gate electrode thereon. The gate electrode is substantially completely salicidized. Spacers are on sidewalls of the gate electrode. The spacers are higher than the gate electrode by a distance. The salicidized source and drain regions extend into the substrate, adjacent to the spacers.

The above and other features of the present invention will be better understood from the following detailed description of the preferred embodiments of the invention that is provided in connection with the accompanying drawings.

### BRIEF DESCRIPTION OF THE DRAWINGS

FIGS. 1A and 1B are schematic cross sectional drawing showing progression of steps of a prior art method for forming a metal gate electrode.

FIGS. 2A-2C are cross sectional drawings showing progression of steps of a first exemplary method for preventing salicidation.

FIG. 2D is a cross sectional drawing showing an exemplary source and drain salicidation without salicidizing the gate electrode during source and drain salicidation shown in FIGS. 2A-2C.

FIGS. 2E and 2F are schematic cross sectional drawings showing a second exemplary method for preventing salicidation.

FIG. 2G is a schematic cross sectional drawing showing an exemplary structure for preventing salicidation.

FIGS. 2H-2J are schematic cross sectional drawings showing progression of steps of salicidizing a gate electrode.

FIG. 2K is a schematic cross sectional drawing showing an exemplary salicidized gate electrode.

FIGS. 3A and 3B are cross sectional views showing an exemplary method for preventing salicidation.

FIG. 3C is a cross sectional drawing showing an exemplary source and drain salicidation without salicidizing the electrode gate during source and drain salicidation shown in FIGS. 3A and 3B.

FIG. 3D is a schematic cross sectional drawing of an exemplary salicidized gate electrode.

FIGS. 4A and 4B are cross sectional views showing an exemplary method for preventing salicidation.

FIG. 4C is a cross sectional drawing showing an exemplary source and drain salicidation without salicidizing the electrode gate during such source and drain salicidation.

FIG. 4D is a schematic cross sectional drawing of an exemplary salicidized gate electrode.

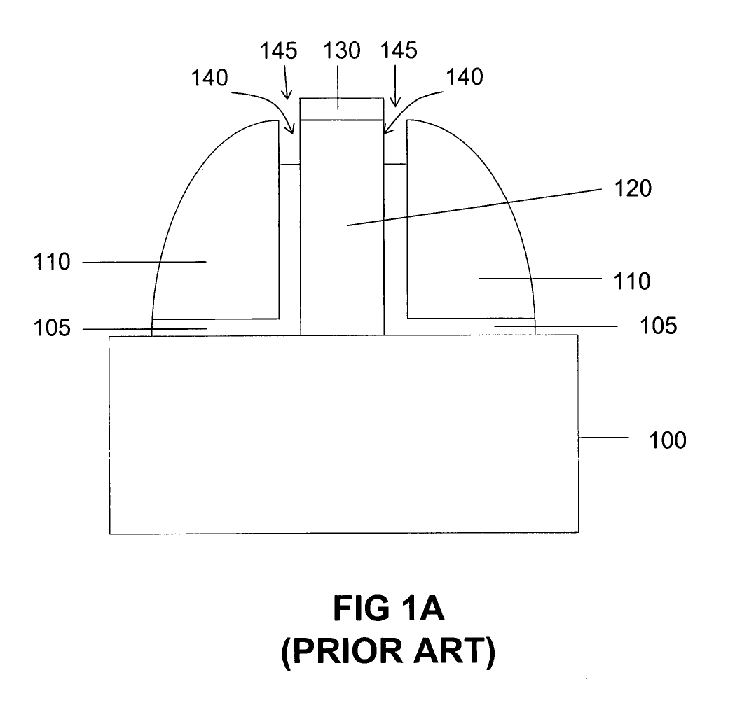

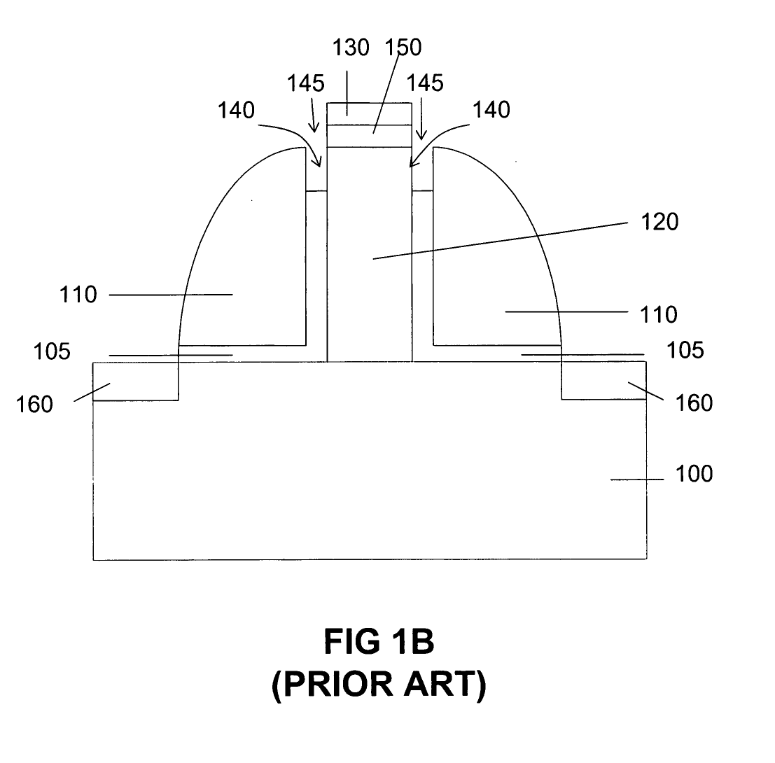

### DETAILED DESCRIPTION OF THE INVENTION

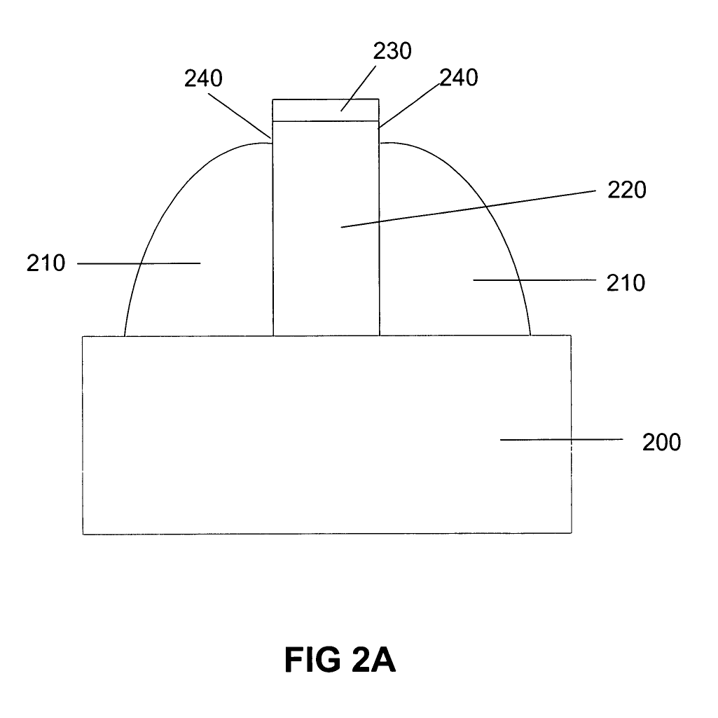

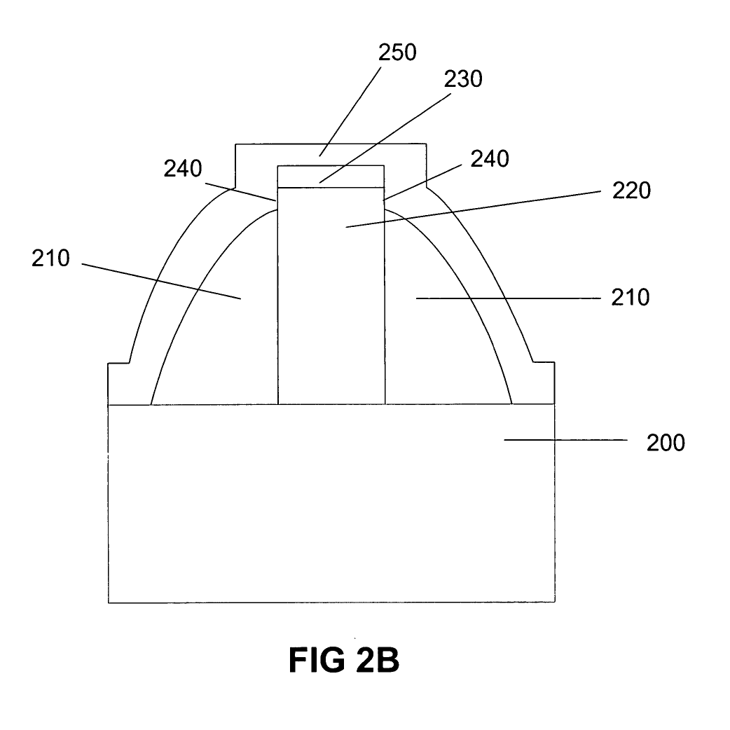

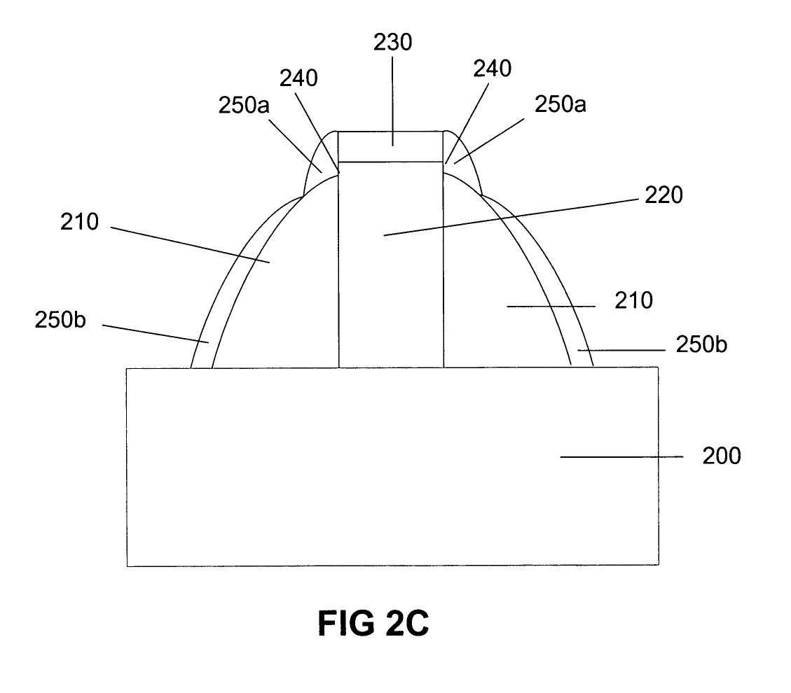

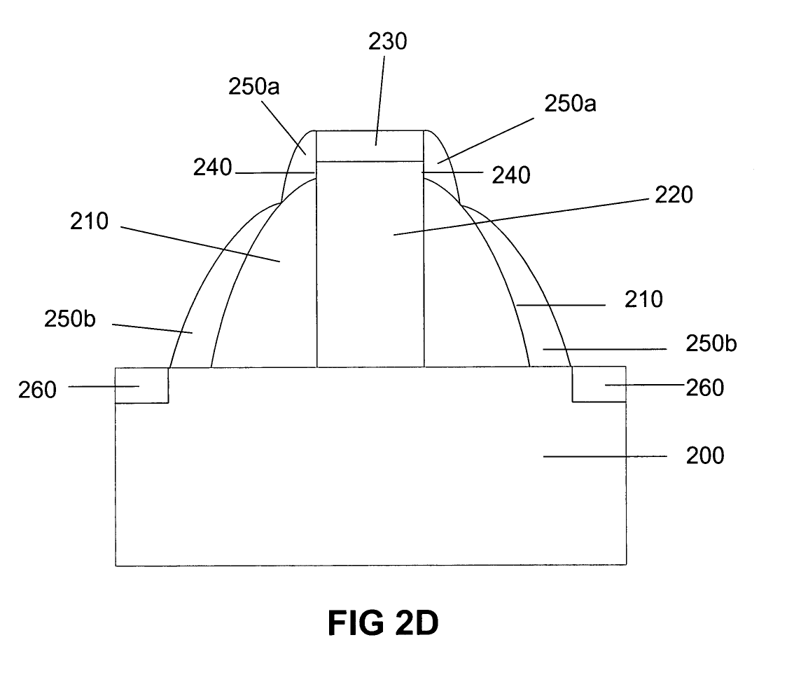

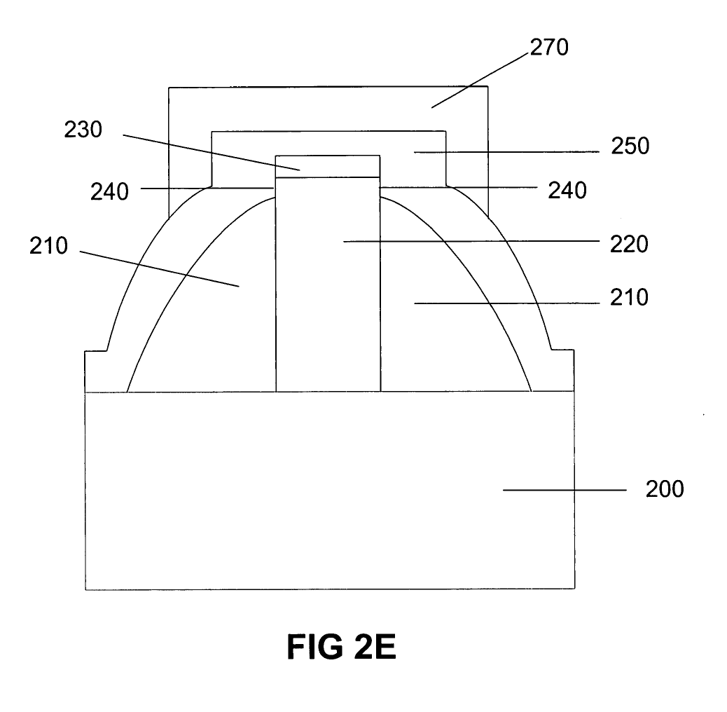

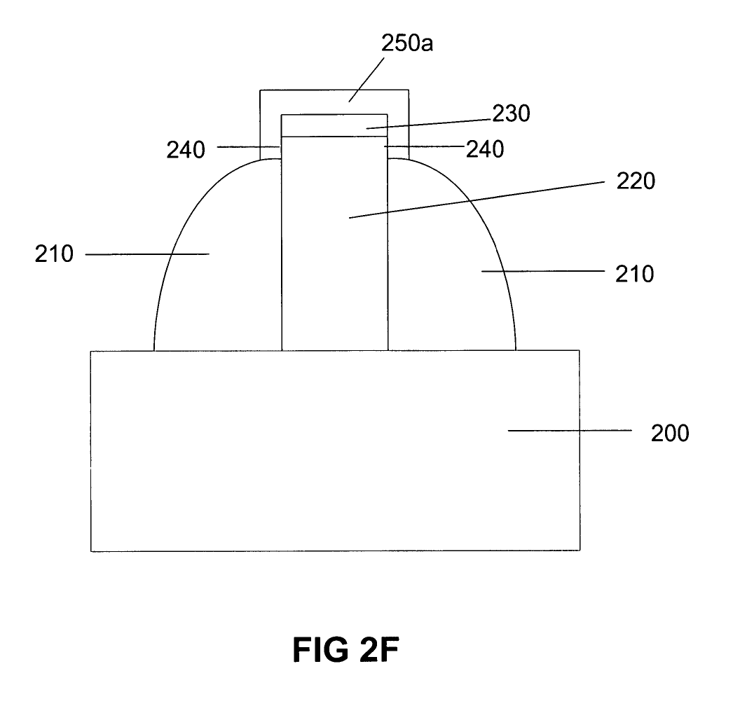

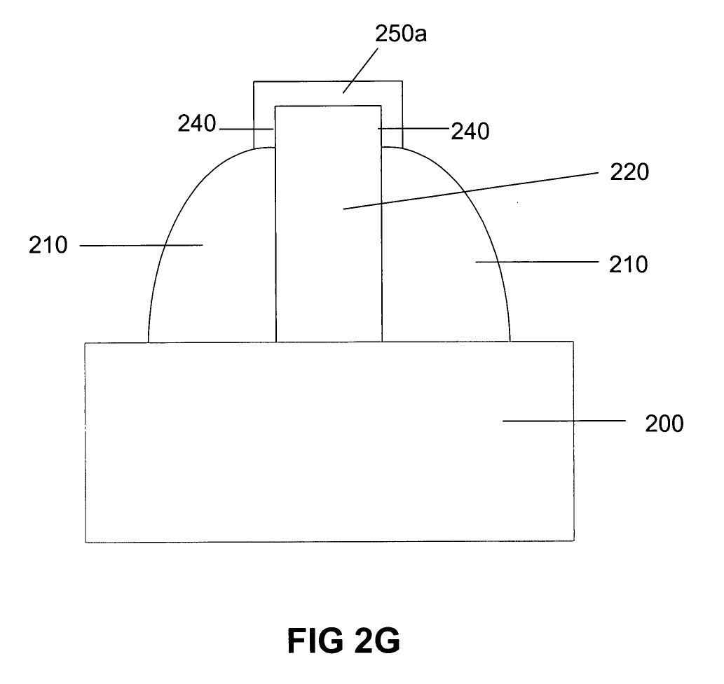

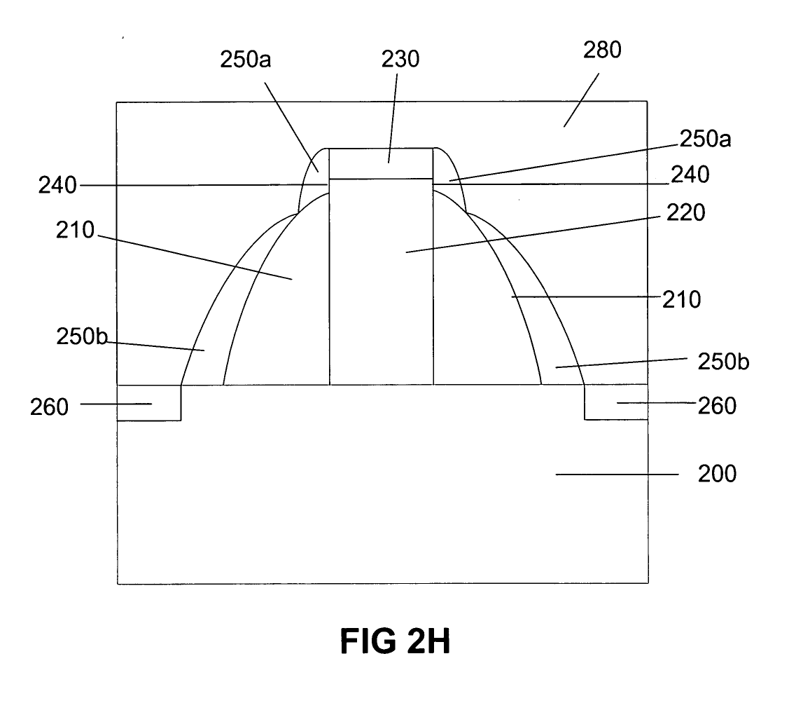

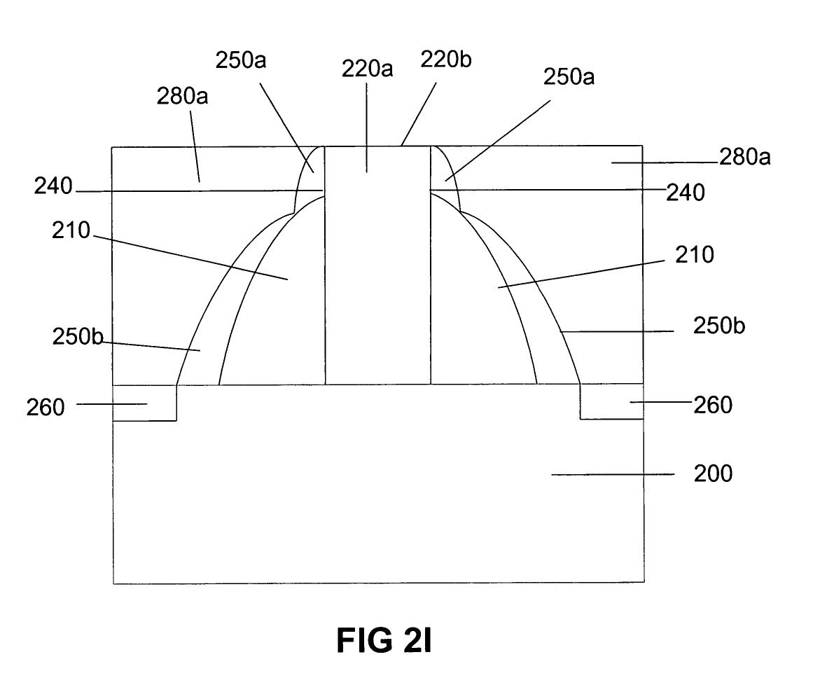

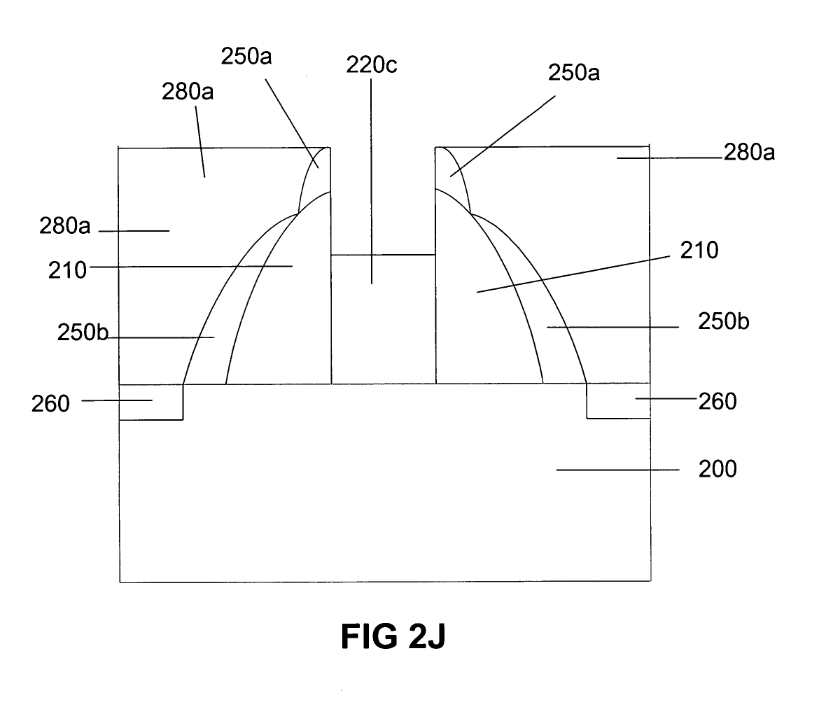

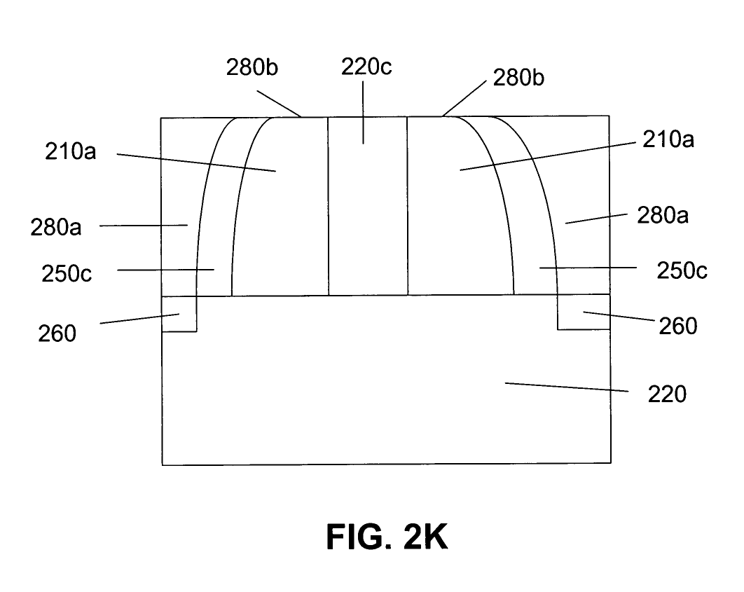

FIGS. 2A-2C are cross sectional drawings showing progression of steps of an exemplary method for preventing salicidation.

Referring to FIG. 2A, the method first provides a substrate 200 having a gate electrode 220 thereon. A mask layer 230 is on the gate electrode 220. Spacers 210 are on the sidewalls of the gate electrode 220, exposing top portions 240 of the sidewalls of the gate electrode 220.

The substrate 200 can be, for example, a silicon substrate, a III-V compound substrate, a glass substrate, or any other substrate similar thereto. The gate electrode 220 can be a material such as doped polysilicon, undoped polysilicon, amorphous silicon or the like. The gate electrode 220 can be formed, for example, by chemical vapor deposition (CVD) with SiH₄ as a reaction gas. The mask layer 230 can be a material such as silicon oxide, silicon nitride or silicon oxy-nitride. The mask layer 230 can be formed, for example, by CVD with dichlorosilane (SiCl₂H₂) and ammonia (NH₃) as reaction gases. The spacers 210 can be a material such as silicon oxide, silicon nitride or silicon oxy-nitride and formed, for example, by CVD. The spacers 210 can be formed to be from about 200 angstroms to about 900 angstroms. The spacers 210 and the mask layer 230 can be the same or different materials.

The method of forming such a structure described above may comprise first forming a gate electrode layer (not shown) over the substrate 200. A hard mask material (not shown) is formed over the gate electrode layer. A photolithographic process and an etch process are applied for patterning the gate electrode layer and the hard mask material so as to form the gate electrode 220 and the mask layer 230. Then a spacer layer (not shown) is formed, substantially conformal over the substrate 200, the gate electrode 220 and the mask layer 230. Usually, an etch-back process is applied to remove portions of the spacer layer on the mask layer 230 and on the substrate 200 for forming the spacers 210. Due to the etch-back process, the top portions 240 of the sidewalls of the gate electrode 220 are exposed as shown in FIG. 2A. If a salicidation process is applied to the structure shown in FIG. 2A, a salicidation reaction occurs on the exposed top sidewalls 240 of the gate electrode 220. That would cause a contamination issue for transistors formed based on the structure of FIG. 2A.

Referring to FIG. 2B, a dielectric material layer 250 is formed over the structure of FIG. 2A. The dielectric material layer 250 can be a dielectric material such as silicon oxide, silicon nitride or silicon oxy-nitride and may be formed, for example, by CVD. The dielectric material layer 250 can be formed to be from about 50 angstroms to about 500 angstroms. Since the exemplary dielectric material layer 250 is substantially conformal over the structure in FIG. 2A, the dielectric material layer 250 covers the exposed top sidewalls 240 of the gate electrode 220. In other embodiments, it is not necessary that the dielectric material layer be conformal over the structure in FIG. 2A. As long as the dielectric material layer 250 can cover the top exposed sidewalls 240 of the gate electrode 220, the method of forming the dielectric material layer 250 can be applied.

Referring to FIG. 2C, an etch process is then applied to remove portions of the dielectric material layer 250 on the mask layer 230 and the substrate 200 so as to form the dielectric layers 250a above the spacers 210 and the dielectric layers 250b on the substrate 200 and the spacers 210. In this embodiment, the etch process is an etch-back process. By the etch-back process, the dielectric layers 250a and 250b are formed to be spacers. The dielectric layers 250a cover the exposed top sidewalls 240 of the gate electrode 220. By covering the top exposed sidewalls 240 of the gate electrode 220, the top exposed sidewalls 240 of the gate electrode 220 are not subject to the subsequent source and drain salicidaiton.

FIG. 2D is a cross sectional drawing showing an exemplary source and drain salicidation without salicidizing the gate electrode during source and drain salicidation shown in FIGS. 2A-2C.

A metal layer (not shown), such as Ti, Ta, W, Co, Hf or Mo, is formed over the structure of FIG. 2C. The metal layer can be formed, for example, by physical vapor deposition (PVD). A thermal treatment is then performed for salicidation. With the spacers 210, the mask layer 230 and the dielectric layers 250a, the gate electrode 220 does not contact the metal layer. The salicidation process forms the salicidized source and drain regions 260 into the substrate 200. After the salicidation, the metal layer is removed and the structure of FIG. 2D is thus acquired. Accordingly, the method forms the salicidized source and drain regions 260 without salicidizing the gate electrode 220 during the salicidation process for the source and drain regions 260. The dielectric layers 250a and 250b do not cover the source and drain regions 260. The contamination issue can be avoided for the transistor which is formed by this exemplary method.

FIGS. 2E and 2F are schematic cross sectional drawings showing another exemplary method for preventing salicidation.

Referring to FIG. 2E, a patterned etch mask layer 270 is formed over the structure in FIG. 2B, covering the dielectric material 250 layer which covers the exposed top sidewalls 240 of the gate electrode 220. The patterned etch mask layer 270 can be a material such as photoresist or dielectric material. In this embodiment, and the patterned etch mask layer 270 is photoresist, the formation of the patterned etch mask layer 270 can be achieved by a photolithographic process. The patterned etch mask layer 270 can be formed, for example, by coating, exposing and developing a photoresist layer (not shown).

Referring to FIG. 2F, a cap layer 250a is formed, covering the exposed top sidewalls 240 of the gate electrode 220. Due to the cap layer 250a, the gate electrode 220 is not subject to a subsequent salicidation process as shown in FIG. 2D. After viewing the exemplary embodiment, one of ordinary skill in the art understands how to determine the structure and the process for preventing the salicidation on the gate electrode 210 while the source and drain regions 260 are salicidized.

In addition, due to the patterned etch mask layer 270 shown in FIG. 2E, even a non-conformal dielectric material 250 can be applied to form the cap layer 250a. The etch process removes the dielectric material 250 which does not cover the exposed top sidewalls 240 of the gate electrode 220. By the patterned etch mask layer 270, the dielectric layers 250b shown in FIG. 2C can be completely removed. Whether the dielectric layers 250b is completely removed depends on the requirements of the structure and the process. One of ordinary skill in the art will understand how much of the dielectric layers 250b should be removed.

In some embodiments, the patterned etch mask layer 270 is a dielectric layer such as silicon oxide, silicon nitride or silicon oxy-nitride. Under such a configuration, a patterned photoresist layer (not shown) should be formed over the dielectric layer for defining the dielectric layer. In such an embodiment, the patterned mask layer 270 can be removed or left on the mask layer 230. Given the requirements of any specific structure or process, one of ordinary skill in the art will understand whether to remove the patterned mask layer 270.

FIG. 2G is a schematic cross sectional drawing showing an exemplary structure of preventing salicidation.

Referring to FIG. 2G, the cap layer 250a is formed, covering the top of the gate electrode 220. In this embodiment, the hard mask layer 230 is not required because the cap layer 250a prevents the salicidation occurring on the top of the gate electrode 220. On the basis of the requirements of a given process, one of ordinary skill in the art will understand whether it is advantageous to use the hard mask layer 230 of FIG. 2G.

FIGS. 2H-2J are schematic cross sectional diagrams showing the progression of steps of salicidizing a gate electrode.

Referring to FIG. 2H, a dielectric layer 280 is formed over the structure in FIG. 2D, covering the salicidized source and drain regions 260. The dielectric layer 280 can be a material such as undoped silicate glass (USG), boron doped silicate glass (BSG), phosphorous doped silicate glass (PSG), boron phosphorous doped silicate glass (BPSG), low-k dielectric material or the like. The dielectric layer 280 can be formed, for example, by Chemical Vapor Deposition (CVD) or spin-on coating.

Referring to FIG. 21, the mask layer 230 and a portion of the dielectric layer 280 are removed so as to expose the top surface 220b of the gate electrode 220a. The method of removing the mask layer 230 and the portion of the dielectric layer 280 includes, for example, Chemical Mechanical Polish (CMP) or an etch-back process. The removing of the mask layer 230 and the portion of the first dielectric layer may also remove portions or all of the dielectric layers 250a. On the basis of requirements of a given structure or the process, one of ordinary skill in the art will understand how much of the dielectric layers 250a should be removed.

Referring to FIG. 2J, a portion of the gate electrode 220a is removed so as to form the gate electrode 220c. After the removing of the portion of the gate electrode 220a, a salicidation process is applied thereto, substantially transforming the gate electrode 220c into a salicidized gate electrode. For the salicidation process, a metal layer (not shown), such as Ti, Ta, W, Co, Hf or Mo, is formed over the structure of FIG. 21. The metal layer can be formed, for example, by physical vapor deposition (PVD). A thermal treatment is then performed for salicidation. Due to the removing of the portion of the gate electrode 220a, the spacers 210 are higher than the gate electrode 220c by a distance from about 10 angstroms to about 1700 angstroms. If the height of the gate electrode 220a is not a concern, the removing of the portion of the gate electrode 220a is not necessarily required. Because the salicidized source and drain regions 260 are covered by the dielectric layers 280a, the salicidation of the gate electrode 220b does not affect the salicidized source and drain regions 260. Accordingly, the salicidized source and drain regions 260 and the salicidized gate electrode 220b may have different thicknesses.

According to FIG. 2J, the structure of gate salicidation includes the salicidized gate electrode 220c on the substrate 200. The spacers 210 are on sidewalls of the gate electrode 220c, which is shorter than the spacers. The salicidized source and drain regions 260 extend into the substrate 200 and are adjacent to the spacers 210. The dielectric layers 250a are above the spacers 210. The dielectric layers 250b are on the spacers 210. The salicidized gate electrode 220c has a thickness from about 200 angstroms to about 500 angstroms. The salicidized gate electrode 220c and the salicidized source and drain regions 260 may have different thicknesses.

In some embodiments, the desired height of the gate electrode 220c can be obtained by CMP or an etch-back process described in FIG. 2I. FIG. 2K is a schematic cross sectional drawing showing an exemplary salicidized gate electrode 220c. In addition to the removal of the mask layer 230 and the portion of the dielectric layer 280, the removing process described with reference to FIG. 2I can also remove a portion of the gate electrode 220a and a portion of the dielectric layers 250b. By the removing process, the desired height of the gate electrode 220c can be acquired, and the removing of the portion of the gate electrode 220a described in FIG. 2J may not be required. In such an embodiment, the structure of gate salicidation comprises the substrate 200 having the salicidized gate electrode 220c thereon. The spacers 280a are on sidewalls of the gate electrode and the spacers 280a have flat top portions 210b. The flat portions 210b of the spacers 210a are formed by CMP or an etch-back process. The dielectric layers 250c are on the spacers 210a. The dielectric layers 250c have flat top portions. The salicidized source and drain regions 260 extend into the substrate 260 and are adjacent to the spacers 260.

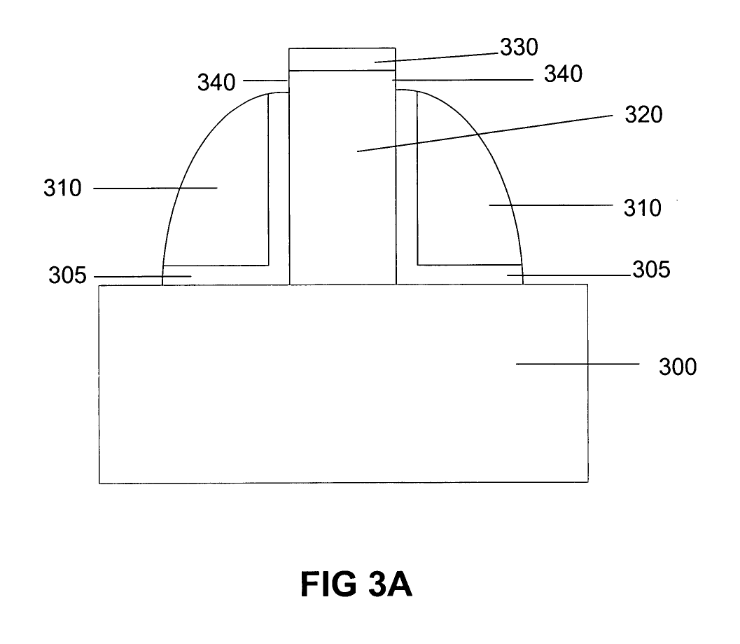

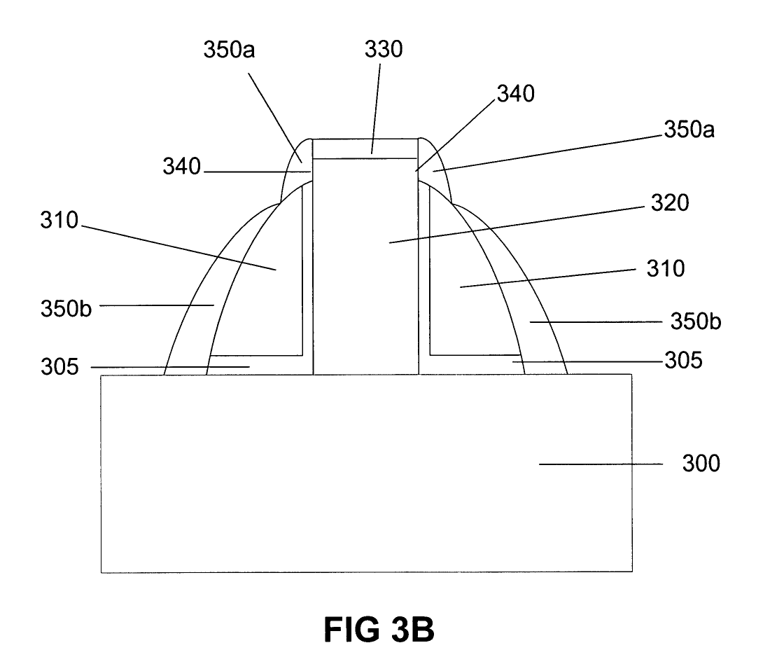

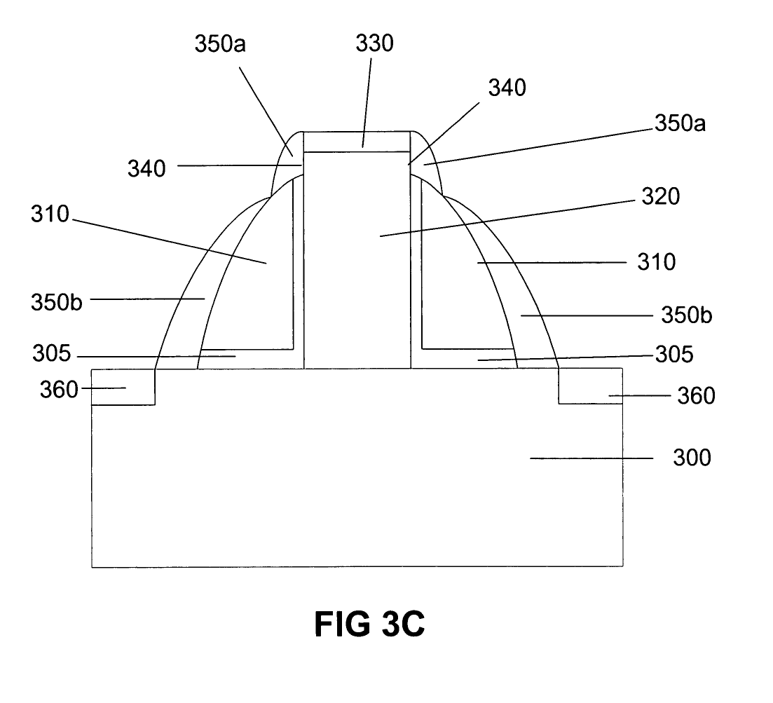

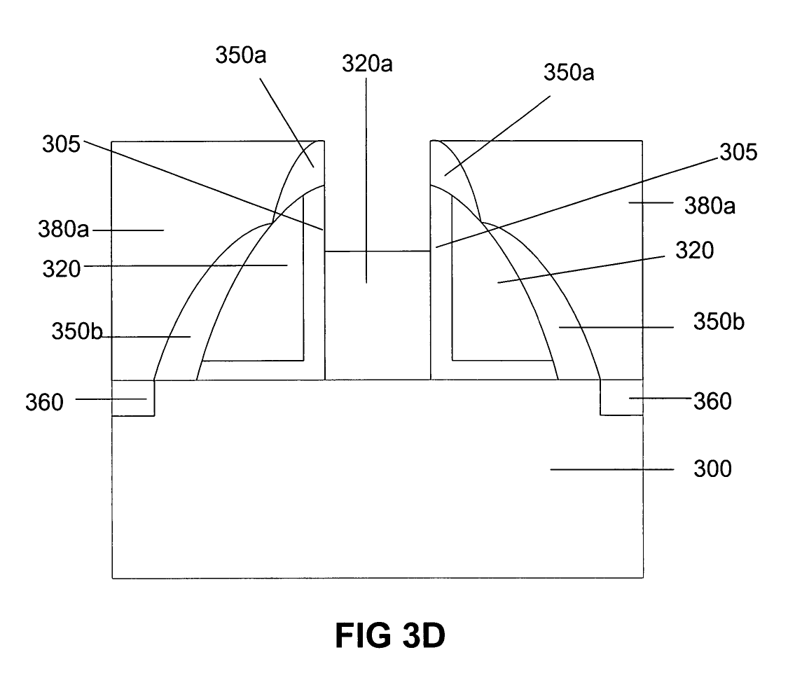

FIGS. 3A and 3B are cross sectional views showing an exemplary method for preventing salicidation. Except of liner layers 315, items of the structure in FIGS. 3A and 3B which are the same items of the structure in FIGS. 2A-2C are identified by reference numerals that are increased by 100. Detailed descriptions of these items are not repeated. The liner layers 315 can be a material such as silicon oxide, silicon nitride or silicon oxy-nitride and formed, for example, by CVD. The liner layers 315 are formed to be from about 50 angstroms to about 500 angstroms.

The method of forming the structure of FIG. 3A may comprise first forming a gate electrode layer (not shown) over the substrate 300. A hard mask material (not shown) is formed over the gate electrode layer. A photolithographic process and an etch process are applied for patterning the gate electrode layer and the hard mask material so as to form the gate electrode 320 and the mask layer 330. A liner material (not shown) is formed, substantially conformal over the substrate 300, the gate electrode 320 and the mask layer 330. Then a spacer layer (not shown) is formed, substantially conformal over the liner material. Usually, an etch-back process is applied to remove portions of the liner material and the spacer layer on the mask layer 330 and on the substrate 300 for forming the liner layers 305 and the spacers 310. Due to the etch-back process, the top portions 340 of the sidewalls of the gate electrode 320 are exposed as shown in FIG. 3A.

Referring to FIG. 3B, the dielectric layers 350a are formed above the liner layers 305 and the spacers 310; the dielectric layers 350b are formed on the spacers 310. The structure of FIG. 3B can be obtained by the same process described in FIG. 2B. Detailed descriptions are not repeated. The method of forming the dielectric layers 250a described in FIGS. 2E-2F can also be applied to this embodiment. Detailed descriptions are not repeated. In this embodiment, the dielectric layers 350a are spacers, covering the exposed top sidewalls of the gate electrode 320. By covering the top exposed sidewalls of the gate electrode 320, the top exposed sidewalls of the gate electrode 320 are not subject to the subsequent salicidation process. In some embodiments, the spacers 310 are higher than the liner layers 305 so as to create divots (not shown) between the gate electrode 320 and the spacers 310. Even if the formation of the divots occurs, the dielectric layers 350a fill into the divots, covering the top exposed sidewalls of the gate electrode 320. Due to the formation of the divots, the thickness of the liner material may vary therewith. Upon reviewing this embodiment, one of ordinary skill in the art will understand how to form the dielectric layers 350a and determine the thickness of the liner material. In another embodiment, the spacers 310 are lower than the liner layers 305. The dielectric layers 350a cover the exposed top sidewalls of the gate electrode 320, even if a step-coverage spacer structure is formed.

FIG. 3C is a cross sectional drawing showing an exemplary source and drain salicidation without salicidizing the gate electrode during source and drain salicidation in FIGS. 3A and 3B.

A metal layer (not shown), such as Ti, Ta, W, Co, Hf or Mo, is formed over the structure of FIG. 3B. The metal layer can be formed, for example, by physical vapor deposition (PVD). A thermal treatment is then performed for salicidation. With the liner layers 305, the spacers 310, the mask layer 330 and the dielectric layers 350a, the gate electrode 220 does not contact the metal layer. The salicidation process forms the salicidized source and drain regions 360 into the substrate 300, which contact the metal layer. After the salicidation, the metal layer is removed and the structure of FIG. 3C is thus acquired. Accordingly, the method forms the salicidized source and drain regions 360 without salicidizing the gate electrode 320 during such salicidation of the source and drain regions 360. The dielectric layers 350a and 350b do not cover the source and drain regions 360. The reliability of the transistor which is formed by this method can thus be enhanced.

FIG. 3D is a schematic cross sectional drawing of an exemplary salicidized gate electrode. The salicidized gate electrode 320a and the dielectric layers 380a are equivalent to the salicidized gate electrode 220c and the dielectric layers 280a, respectively. Moreover, the method of forming the salicidized gate electrode 320a can be substantially similar to that described in FIGS. 2H-2J. Detailed descriptions are not repeated.

In this embodiment, because the salicidized source and drain regions 360 are covered by the dielectric layers 380a, the salicidation of the gate electrode 320a does not affect the salicidized source and drain regions 360. Accordingly, the salicidized source and drain regions 360 and the salicidized gate electrode 320a may have different thicknesses.

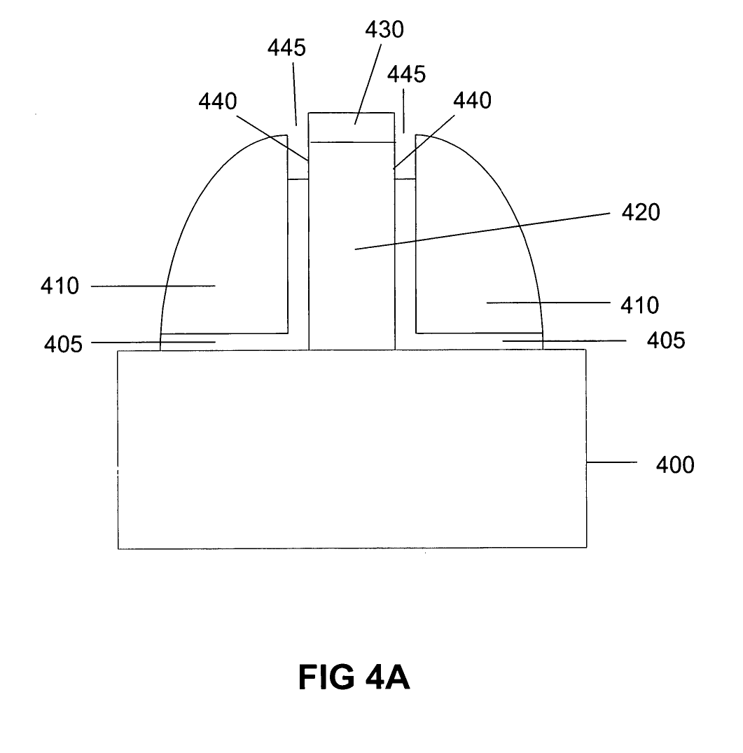

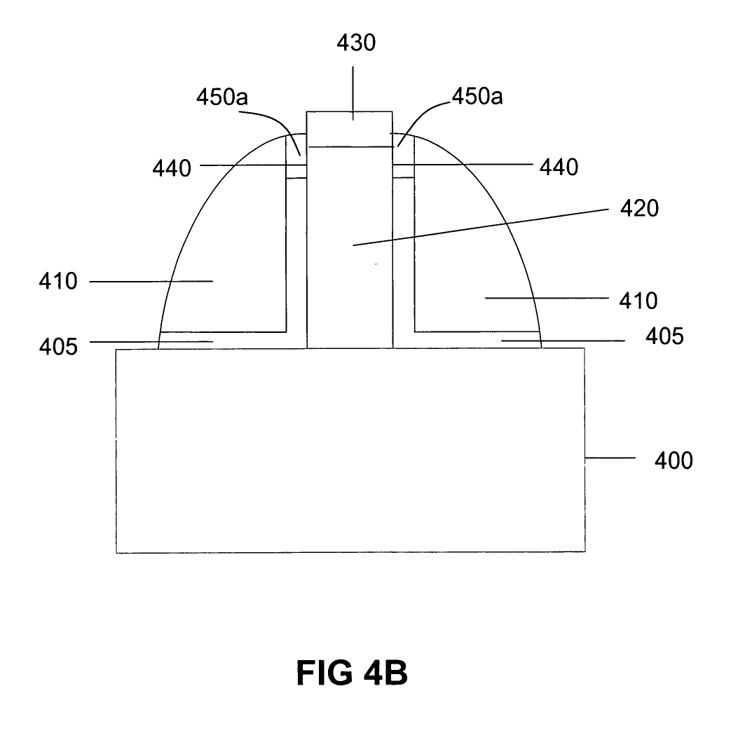

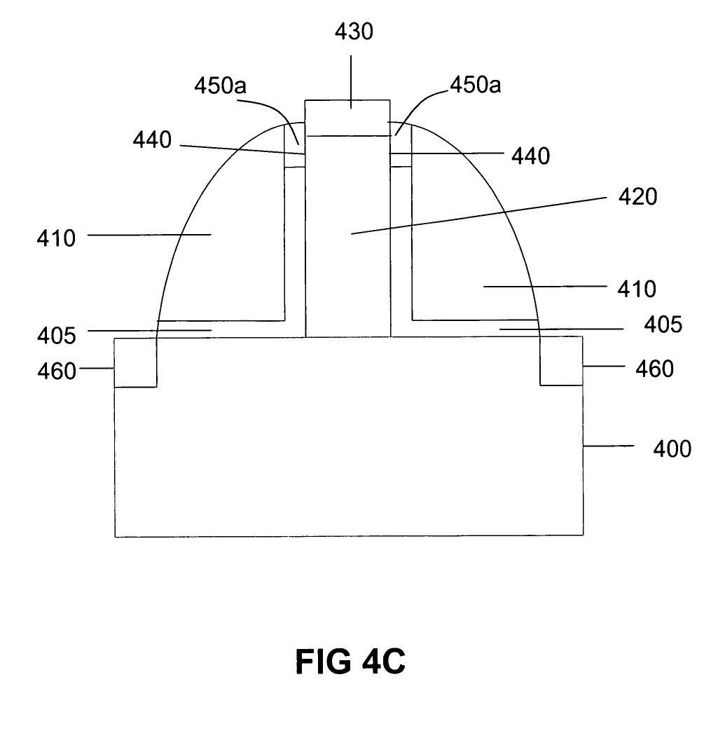

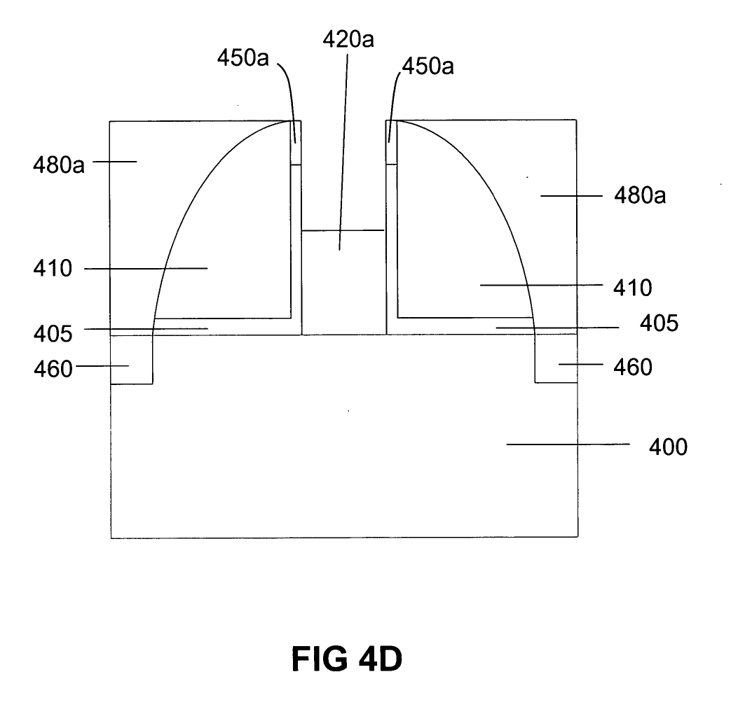

FIGS. 4A and 4B are cross sectional views showing an exemplary method for preventing salicidation. Except for dielectric layers 415, items of the structure in FIGS. 4A and 4B which are the same as items of the structure in FIGS. 3A and 3B are identified by reference numerals that are increased by 100. Detailed descriptions of these items are not repeated. The dielectric layers 415 is a material such as silicon oxide, silicon nitride or silicon oxy-nitride and formed by, for example, CVD or spin coating.

The method of forming the structure of FIG. 4A can be substantially similar to that described with reference to FIG. 3A. Detailed descriptions are not repeated. Due to the etch-back process, divots 445 are formed on the liner layers 405 and between the spacers 410 and the gate electrode 420. With the divots 445, the top portions 440 of the sidewalls of the gate electrode 420 are exposed.

Referring to FIG. 4B, the dielectric layers 450a are formed above the liner layers 405, filling in the divots 445.

The method for forming the structure in FIG. 4B may comprise first forming a dielectric material (not shown) over the structure in FIG. 4A. The dielectric material can be formed, for example, by CVD or spin-on coating. The dielectric material fills into the divots 445, covering the exposed top sidewalls 440 of the gate electrode 420. An etch process is then performed to remove the dielectric material outside of the divots 445a so as to form the dielectric layers 450a in the divots 445. In some embodiments, the dielectric layers 450a can be formed by a photographic process and an etch process. The method of forming the dielectric layers 250a described in FIGS. 2E-2F can also be applied to this embodiment. Detailed descriptions are not repeated.

FIG. 4C is a cross sectional drawing showing an exemplary source and drain salicidation without salicidizing the gate electrode while source and drain salicidation FIGS. 4A and 4B.

A metal layer (not shown), such as Ti, Ta, W, Co, Hf or Mo, is formed over the structure of FIG. 4B. With the liner layers 405, the spacers 410 and the mask layer 430, the gate electrode 420 does not contact the metal layer. The salicidation process forms the salicidized source and drain regions 460 into the substrate 400, which contact the metal layer. After the salicidation, the metal layer is removed and the structure of FIG. 4C is thus acquired. Accordingly, the method forms the salicidized source and drain regions 460 without salicidizing the gate electrode 420 during such salicidation of the source and drain regions 460. The dielectric layers 450a do not cover the source and drain regions 460. The reliability of the transistor which is formed by this method can thus be enhanced.

FIG. 4D is a schematic cross sectional drawing of an exemplary salicidized gate electrode. The salicidized gate electrode 420a and the dielectric layers 480a are equivalent to the salicidized gate electrode 220c and the dielectric layers 280a, respectively. Moreover, the method of forming the salicidized gate electrode 420a can be substantially similar to that described above with reference to FIGS. 2H-2J. Detailed descriptions are not repeated.

According to FIG. 4D, the structure of gate salicidation includes the salicidized gate electrode 420a on the substrate 400. The spacers 410 are on sidewalls of the gate electrode 420a which is shorter than the spacers. The liner layers 405 are between the gate electrode 420a and the spacers 410. The salicidized source and drain regions 460 extend into the substrate 400 and are adjacent to the spacers 410. The spacers 410 are higher than the liner layers 405. The liner layers 405 are higher than the gate electrode 420a. The dielectric layers 450a are on the liner layers 405 so as to make a height of the combination of the liner layers 405 and the dielectric layers 450a substantially equal to that of the spacers 410. The salicidized gate electrode 420a has a thickness from about 200 angstroms to about 500 angstroms. The salicidized gate electrode 420a and the salicidized source and drain regions 460 may have different thicknesses.

In this embodiment, because the salicidized source and drain regions 460 are covered by the dielectric layers 480a, the salicidation of the gate electrode 420a does not affect the salicidized source and drain regions 460. Accordingly, the salicidized source and drain regions 460 and the salicidized gate electrode 420a may have different thicknesses.

Although the invention has been described and illustrated with reference to specific illustrative embodiments thereof, it is not intended that the invention be limited to those illustrative embodiments. Those skilled in the art will recognize that variations and modifications can be made without departing from the spirit of the invention. It is therefore intended to include within the invention all such variations and modifications which fall within the scope of the appended claims and equivalents thereof.

What is claimed is:

1. A method for preventing salicidation on a gate structure, which comprises:
providing a substrate having an gate electrode thereon, spacers on sidewalls of the gate electrode, exposing a surface on or adjacent to a top portion of the gate electrode; and
forming a dielectric layer above the spacers, covering the exposed surface of the gate electrode without covering a source or drain region of the substrate.

2. The method of claim 1, further comprising forming a mask layer on the gate electrode wherein the exposed surface of the gate electrode includes top portions of sidewalls of the gate electrode.

3. The method of claim 2, wherein forming the dielectric layer above the spacers comprises:
forming a dielectric material over the substrate, the mask layer and the spacers; and
etching back the dielectric layer.

4. The method of claim 1, wherein the step of forming the dielectric layer above the spacers comprises:
forming a dielectric material over the substrate, the gate electrode and the spacers;
forming a patterned etch mask over the dielectric material, which covers the top of the sidewalls of the gate electrode covering the dielectric material; and
removing a portion of the dielectric material which is not covered by the patterned etch mask so as to form the dielectric layer covering the exposed sidewalls of the gate electrode.

5. The method of claim 4, wherein the step of forming the patterned etch mask over the dielectric material comprises a photolithographic process.

6. The method of claim 4, wherein the step of forming a patterned etch mask over the dielectric material comprises:
forming another dielectric material over the dielectric material layer; and
patterning the another dielectric material with a photolithographic process and an etch process so as to form the patterned etch mask.

7. The method of claim 1, further comprising forming liner layers between the spacers and the gate electrode.

8. The method of claim 7, wherein divots are formed on the liner layers and between the gate electrode and the spacers.

9. The method of claim 8, wherein the step of forming the dielectric layer fills the divots.

10. The method of claim 9, further comprising forming a mask layer on the gate electrode wherein portions of the exposed surface of the gate electrode includes top portions of sidewalls of the gate electrode.

11. The method of claim 10, wherein the step of forming the dielectric layer above the spacers comprises:
forming a dielectric material over the substrate, the mask layer and the spacers; and
etching back the dielectric layer.

12. The method of claim 9, wherein the step of forming the dielectric layer above the spacers comprises:
forming a dielectric material over the substrate, the gate electrode and the spacers;
forming a patterned etch mask over the dielectric material, which covers the top of the sidewalls of the gate electrode covering the dielectric material; and
removing the dielectric material which is not covered by the patterned etch mask so as to form the dielectric layer covering the exposed sidewalls of the gate electrode.

13. The method of claim 12, wherein the step of forming the patterned etch mask over the dielectric material comprises a photolithographic process.

14. The method of claim 12, wherein the step of forming a patterned etch mask over the dielectric material comprises:
forming another dielectric material over the dielectric material layer; and
patterning the another dielectric material with a photolithographic process and an etch process so as to form the patterned etch mask.

15. A method of salicidizing source and drain regions, comprising providing a substrate having an gate electrode thereon, spacers on sidewalls of the gate electrode, exposing a surface on or adjacent to a top portion of the gate electrode;
forming a dielectric layer above the spacers, covering the exposed surface of the gate electrode; and
salicidizing source and drain regions which are adjacent to the spacers without forming salicidation on the gate electrode while salicidizing the source and drain regions.

16. The method of salicidizing source and drain regions of claim 15, further comprising forming liner layers between the gate electrode and the spacers.

17. A method of salicidizing a gate electrode, comprising:
providing a substrate having a gate electrode thereon, spacers on sidewalls of the gate electrode, exposing a surface on or adjacent to a top portion of the gate electrode;
forming a first dielectric layer above the spacers, covering the exposed surface of the gate electrode;
salicidizing source and drain regions which are adjacent to the spacers without forming salicidation on the gate electrode while salicidizing the source and drain regions;
forming a second dielectric layer covering the salicidized source and drain regions;
removing a portion of the first dielectric layer so as to expose a top surface of the gate electrode; and
salicidizing the gate electrode.

18. The method of salicidizing a gate electrode of claim 17, further comprising forming liner layers between the gate electrode and the spacers.

19. The method of salicidizing a gate electrode of claim 17, further comprising removing a portion of the gate electrode.

20. The method of salicidizing a gate electrode of claim 17, wherein salicidizing the gate electrode substantially completely salicidizing the gate electrode.

21. A structure for preventing salicidation on a gate structure, comprising:
a substrate having a gate electrode thereon;
spacers on sidewalls of the gate electrode, exposing a surface on or adjacent to a top portion of the gate electrode; and
a dielectric layer above the spacers, covering the exposed surface of the gate electrode without covering a source or drain region of the substrate.

22. The structure of claim 21, wherein the dielectric layer comprises a cap layer.

23. The structure of claim 21, further comprising a mask layer on the gate electrode wherein the exposed surface of the gate electrode includes top portions of sidewalls of the gate electrode.

24. The structure of claim 23, wherein the dielectric layer comprises spacers.

25. The structure of claim 21, further comprising liner layers between the spacers and the gate electrode.

26. The structure of claim 25, further comprising divots on the liner layers and between the gate electrode and the spacers.

27. The structure of claim 26, wherein the dielectric layer fills in the divots, covering the exposed top portions of the sidewalls of the gate electrode.

28. The structure of claim 26, wherein the dielectric layer comprises a cap layer.

29. The structure of claim 26, further comprising a mask layer on the gate electrode.

30. The structure of claim 29, wherein the dielectric layer comprises spacers, covering the exposed top sidewalls of the gate electrode.

31. A semiconductor device, comprising:
a substrate having an gate electrode thereon, the gate electrode substantially completely salicidized;
spacers on sidewalls of the gate electrode, the spacers being higher than the gate electrode by a distance; and
salicidized source and drain regions extending into the substrate, adjacent to the spacers.

32. The structure of claim 31, wherein the salicidized gate electrode and the salicidized source and drain regions have different thicknesses.

33. The semiconductor device of claim 31, further comprising liner layers between the spacers and the gate electrode.

34. The semiconductor device of claim 33, wherein the spacers are higher than the liner layers.

35. The semiconductor device of claim 34, wherein the liner layers are higher than the gate electrode.

36. The semiconductor device of claim 33, further comprising dielectric layers above the liner layers so as to make a height of the combination of the liner layers and the dielectric layers substantially equal to a height of the spacers.

37. The semiconductor device of claim 36, further comprising another dielectric layers on the spacers.

38. The semiconductor device of claim 31, further comprising dielectric layers above the spacers.

39. The semiconductor device of claim 38, further comprising another dielectric layers on the spacers.

40. The semiconductor device of claim 31, wherein the distance is from about 10 angstroms to about 1700 angstroms.

41. The semiconductor device of claim 31, wherein the gate electrode has a thickness from about 200 angstroms to about 500 angstroms.

42. A structure of source or drain salicidation, comprising:
a substrate having a gate electrode thereon, the gate electrode substantially completely salicidized;
spacers on sidewalls of the gate electrode, the spacers having flat top portions; and
salicidized source and drain regions extending into the substrate, adjacent to the spacers.

43. The structure of claim 42, further comprising liner layers between the spacers and the gate electrode.

44. The structure of claim 42, wherein the gate electrode has a thickness from about 200 angstroms to about 500 angstroms.

45. The structure of claim 42, further comprising additional spacers on the spacers, the additional spacers having another fate top portions.

46. A structure of gate salicidation formed by the process of claim 17.
